(19) United States
(12) Patent Application Publication
(10) Pub. No.: US 2003/0062551 A1
(43) Pub. Date: Apr. 3, 2003

(54) Electrode structure including encapsulated adhesion layer

(75) Inventor: Xingfu Chen, Simsbury, CT (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: JDS Uniphase Corporation, San Jose, CA

(21) Appl. No.: 10/261,877

(22) Filed: Oct. 1, 2002

Related U.S. Application Data
(60) Provisional application No. 60/326,809, filed on Oct. 2, 2001.
(60) Provisional application No. 60/332,173, filed on Nov. 9, 2001.

(51) Int. Cl. H01L 27/10

(52) U.S. Cl. 257/211

(57) ABSTRACT

The present invention relates to methods for forming metalized structures, such as electrodes, on non-conductive substrates of electronic and electro-optic devices for enhanced corrosion resistance. In the method of the present invention, an electrode layer is deposited over an adhesion layer on a substrate surface including all edges of the adhesion layer not in contact with the substrate, thereby encapsulating the adhesion layer within the electrode metal before forming the electrode. Prior art multi-layer metalized structures have a galvanic corrosion problem when exposed to moisture, owing to the differences in electrochemical potentials of the dissimilar metals. Galvanic corrosion cells are created at areas of water condensation during device service. Such galvanic corrosion can cause current leakage, short circuit, or other problems causing device failures. By encapsulating all surfaces of the adhesion layer not in contact with the substrate, in accordance with the present invention, galvanic corrosion can be prevented.

### CROSS-REFERENCE TO RELATED APPLICATIONS

The present application claims the benefit of co-pending Provisional U.S. Patent Application Serial No. 60/326,809, filed Oct. 2, 2001, entitled: “Electrode Structure Including Gold-Encapsulated Adhesion Layer,” by Xingfu Chen, and Provisional U.S. Patent Application Serial No. 60/332,173, filed Nov. 9, 2001, entitled: “Metalization Structures with Encapsulated Inner Layers(s) for Enhanced Corrosion Resistance,” by Xingfu Chen, both assigned to the assignee of the present application and the disclosures of which are incorporated herein.

### FIELD OF THE INVENTION

The present invention relates generally to the fabrication of electronic and electro-optic devices. In particular, the present invention relates to methods for forming metalized structures, such as electrodes, on non-conductive substrates for enhanced corrosion resistance.

### BACKGROUND OF THE INVENTION

Substrate metalization has been widely used in microelectronics and optoelectronics industries. It is often necessary to apply one or more inner metal layers in addition to the desired top metal layer to a substrate to form a functional metalized structure. The metalized structures may consist of two or more dissimilar metals due to various requirements such as adhesion, diffusion barrier, thermal barrier, oxidation resistance, and so on. Such multi-layer metalized structures have a galvanic corrosion problem when exposed to moisture, owing to the differences in electrochemical potentials of the dissimilar metals. Galvanic corrosion cells are created at areas of water condensation during device service. Such galvanic corrosion can cause current leakage, short circuit, or other problems causing device failures.

Many electronic and electo-optic devices include electrically conductive electrodes formed on the substrate material. Gold is commonly used as an electrode material because it exhibits high electrical conductivity and excellent resistance to chemical corrosion. Copper and platinum are also used as electrode materials. These materials, however, do not readily adhere to typical substrate materials. For example, gold does not easily adhere to lithium niobate, which is an electro-optic substrate material that is used in devices, such as light modulators for optical communication systems.

Adhesion layers are sometimes deposited on the substrate prior to depositing the electrodes to improve the adhesion. Known adhesion layers are thin film layers of an active metal or metal alloy that has good adhesion to a desired substrate and good adhesion to gold or other electrode metals. For example, chromium, titanium, or titanium-tungsten (TiW) adhesion layers have been used to form gold electrodes on lithium niobate substrates.

The electrodes are typically deposited on the adhesion layer by electroplating. The adhesion layer between the gold electrodes is then etched away, thereby leaving completed electrodes that form electrical contact to the device. Electrodes formed with known methods of fabricating gold electrodes with an adhesion layer are sometimes unreliable.

Galvanic corrosion caused by the presence of dissimilar metals can occur around the electrode-adhesion layer interface when the device is exposed to moisture and ionic contamination. The active metal adhesion layer functions as an anode and corrodes in the presence of moisture and condensation inside the device package. Corrosion can negatively impact the performance and reduce the service life of an electronic or electro-optic device.

Another problem with known adhesion layers is that the final etching step to remove the adhesion layer between the electrodes can undercut the adhesion layer beneath the electrode. The undercut can negatively affect the performance of electronic or electro-optic devices. The undercut can also trap moisture and contaminants and thus increase galvanic corrosion.

Galvanic corrosion can be reduced by reducing the amount of moisture around the eletrode-active metal interface. This is sometimes difficult or impossible to accomplish if the device is not hermetically sealed. Galvanic corrosion can even occur in hermetically sealed devices in some circumstances. For example, galvanic corrosion can occur if moisture is present during the hermetic sealing process, if out-gassing occurs from packaging materials, or if leaks occur in the package after it is sealed.

### SUMMARY OF THE INVENTION

A method to reduce corrosion at adhesion layers formed between electrodes and electronic or electro-optic substrates is described. In the method of the present invention, an electrode layer is deposited over an adhesion layer on a substrate surface including all edges of the adhesion layer not in contact with the substrate, thereby encapsulating the adhesion layer before forming the gold electrode. There are numerous methods for forming the encapsulated adhesion layer of the present invention.

Accordingly, the present invention provides a multilayer metalized structure comprising:

a first adhesion layer of a first metal deposited on a substrate;

a second encapsulation layer of a second metal deposited upon the first layer, such that the second layer covers all edges of the first layer not in contact with the substrate.

A further embodiment of the present invention provides a multilayer electrode structure on a semiconductor device comprising:

a first adhesion layer of a first metal deposited on a substrate;

a second encapsulation layer of a second metal deposited upon the first layer, such that the second layer covers all edges of the first layer not in contact with the substrate; and,

an electrode layer of the second metal covering the encapsulation layer.

A further method in accordance with the invention provides forming a metalized structure on a substrate comprising the steps of:

depositing an adhesion layer of a first metal on a surface of the substrate;

etching the adhesion layer selectively to define contact areas;

depositing an encapsulation layer of a second metal on the surface of the substrate and upon the adhesion layer, such that the encapsulation layer covers all edges of the adhesion layer not in contact with the substrate;

fabricating a metalized structure over the encapsulation layer in the contact areas, the metalized structure being formed of a metal identical to or having similar electrochemical potential to the encapsulation layer;

etching the encapsulation layer about the metalized structures in the contact areas.

### BRIEF DESCRIPTION OF THE DRAWINGS

The objects, features and advantages of the invention will be apparent from the following more particular description of embodiments of the invention. The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 illustrates a schematic cross-sectional view diagram of a prior art electrode structure that is fabricated on the top surface of an electro-optic substrate, such as a lithium niobate substrate.

FIG. 2 illustrates a schematic cross-sectional view diagram of an electrode structure that is fabricated on the top surface of an electro-optic substrate that includes an encapsulated adhesion layer according to the present invention.

FIG. 3 schematically illustrates a series of processing steps that can be used to fabricate the electrode structure having an encapsulated adhesion layer according to the present invention.

### DETAILED DESCRIPTION OF THE PREFERRED EMBODIMENT

The present invention relates to reducing galvanic and other corrosion of electrodes fabricated on electronic and electro-optic substrates. An electrode according to the present invention includes an encapsulated adhesion layer that reduces galvanic corrosion around the interface between the adhesion layer and the electrode.

Encapsulating the adhesion layer according to the present invention isolates the junction between the adhesion layer and the electrode from moisture and other contaminants, thereby reducing or eliminating galvanic corrosion caused by dissimilar metals in the presence of moisture. In addition, encapsulation of the adhesion layer according to the present invention reduces or eliminates the undercut of the adhesion layer that can occur beneath the electrode using known fabrication methods. Elimination of the undercut is accomplished by eliminating the final etching step of the adhesion layer that creates the undercut using known methods.

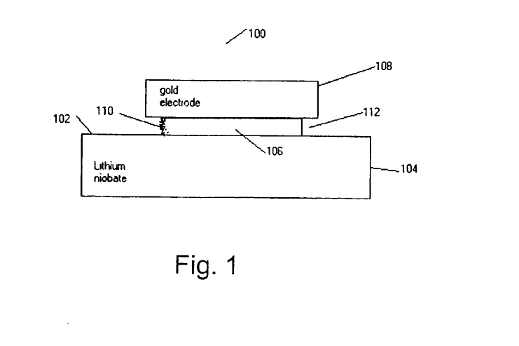

FIG. 1 illustrates a schematic cross-sectional view diagram of a prior art electrode structure 100 that is fabricated on the top surface 102 of an electro-optic substrate 104, such as a lithium niobate substrate. The prior art electrode structure 100 is fabricated on the substrate 104 using methods that are well known in the art. The prior art electrode structure 100 includes a non-encapsulated adhesion layer 106 that is formed directly on the substrate 104. A gold electrode 108 is then formed directly on top of the non-encapsulated adhesion layer 106. The non-encapsulated adhesion layer 106 is then etched in regions of the substrate that do not include the electrode structure. Electrodes that are formed using known methods typically exhibit an undercut 112 that results from the isotropic etching of the non-encapsulated adhesion layer 106.

Galvanic corrosion 110 occurs at the undercut region of the electrode 108 where the non-encapsulated adhesion layer 106 is exposed to the ambient environment. For example, galvanic corrosion, as illustrated in FIG. 1, has been observed, on lithium niobate substrates with a Ti—W adhesion layer.

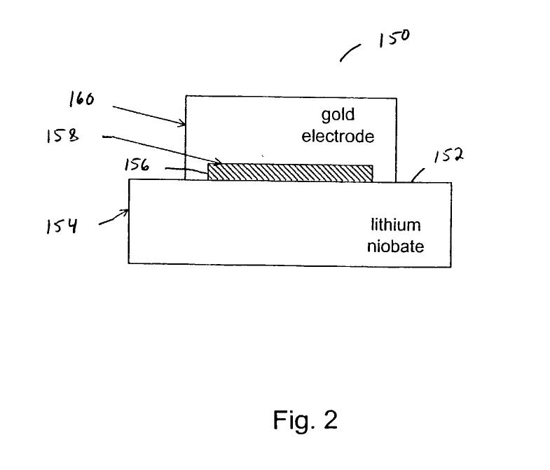

FIG. 2 illustrates a schematic cross-sectional view diagram of an electrode structure 150 that that is fabricated on the top surface 152 of an electro-optic substrate 154 that includes an encapsulated adhesion layer 156 according to the present invention. In one embodiment, the electro-optic substrate 154 is a lithium niobate substrate. The encapsulated adhesion layer 156 is formed directly on the substrate 154 in the contact areas. The encapsulated adhesion layer 156 may be formed by numerous methods that are known in the art. For example, the encapsulated adhesion layer 156 may be formed by sputtering the adhesion layer and then etching the adhesion layer outside of the contact areas.

An encapsulation layer 158 of a metal identical to or having similar electrochemical potential to the outer electrode layer is deposited on the top surface 152 of the entire substrate 154 including the contact areas and adjacent areas. The encapsulation layer 158 can be deposited by numerous methods that are known in the art, such as sputtering. The encapsulation layer 158 encapsulates all surfaces and edges of the etched adhesion layer 156 not in contact with the substrate. Electrodes 160 are then fabricated on the encapsulation layer 158. The electrodes 160 can be fabricated by numerous methods that are known in the art, such as deposition and plating method. For example, the electrodes 160 may be deposited by first lithographically defining the electrodes and then electroplating the electrodes to the desired height.

The encapsulation layer outside of the contact areas is then removed by etching. For example, chemical etching can be used to remove the encapsulation layer outside of the contact areas. The resulting electrode structure 150 includes an embedded adhesion layer 156 that is isolated from the ambient environment. Since the final etching step removes only gold or other suitable encapsulation material, the electrode structure 150 is not undercut, and the adhesion layer 156 remains encapsulated. The electrode structure 150 including the encapsulated adhesion layer 156 according to the present invention can include numerous types of adhesion layers and electrode materials.

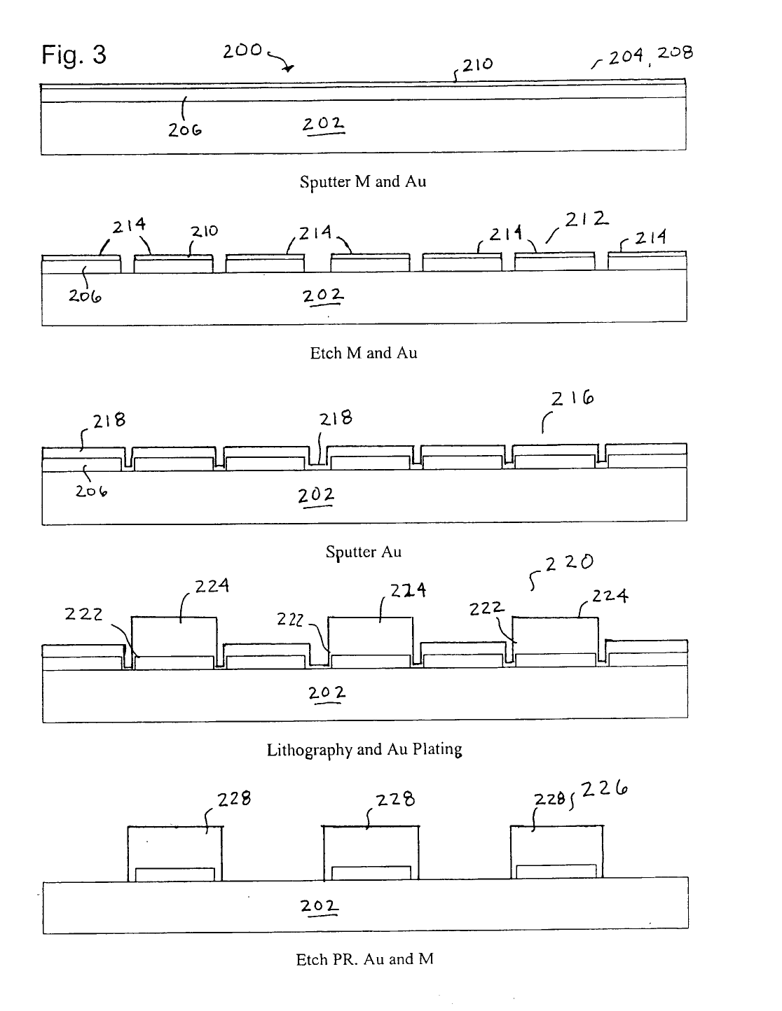

FIG. 3 schematically illustrates a series of processing steps 200 that can be used to fabricate the electrode structure having an encapsulated adhesion layer according to the present invention. An electro-optic substrate 202 is provided. In one embodiment, the electro-optic substrate 202 is a piezoelectric substrate, such as lithium niobate or lithium tantalate, or substrates such as silicon and gallium arsenide.

An adhesion layer deposition step 204 is performed to deposit an adhesion layer 206 on the substrate 202. In one embodiment, the adhesion layer 206 is an active metal, such as a transition metal or an alloy including a transition metal or a transition metal alloy. In one embodiment, the adhesion layer 206 includes chromium, titanium, or titanium-tungsten. Other suitable materials include aluminum, nickel-chromium, tantalum, vanadium, and molybdenum. In one embodiment of the invention, the thickness of the adhesion layer 206 is between 250 and 1,200 Angstroms. The adhesion layer 206 may be formed by numerous deposition methods, such as sputtering, electroless plating, evaporation, and vapor deposition.

A anti-oxidation layer deposition step 208 is then performed to deposit a gold anti-oxidation layer 210 on the adhesion layer 206 to prevent oxidation of the adhesion layer 206. The anti-oxidation layer is typically the same material as the encapsulation layer. In one embodiment, the thickness of the gold anti-oxidation layer 210 is between 100 and 1,000 Angstroms. The anti-oxidation layer 210 may be formed by numerous deposition methods, such as sputtering and evaporation. The anti-oxidation layer 210 is preferably sputter deposited in the vacuum chamber immediately following sputter deposit of the adhesion layer. If the adhesion layer is not easily oxidized, this step can be omitted.

A first etching step 212 is performed to etch areas of the gold layer 210 and the adhesion layer 206 outside of the contact areas 214, thereby leaving the adhesion layer 206 and the gold layer 210 in the adhesion layer contact areas 214. The first etch step 212 can be performed by numerous methods that are well known in the art. For example, the areas of the adhesion layer 206 and the gold anti-oxidation layer 210 outside of the contact area 214 can be defined lithographically and then chemically etched or etched using plasma etching or ion milling.

A gold encapsulation layer deposition step 216 is performed to deposit a gold encapsulation layer 218 on the top surface of the substrate 202, the gold anti-oxidation layer 210, and the edges of the adhesion layer 206 not in contact with the substrate. The gold encapsulation layer 218 covers the adhesion contact areas 214 and the surrounding areas, thereby encapsulating the adhesion layer 214. In one embodiment, plating techniques are used to fabricate the gold electrode. In this embodiment, the gold encapsulation layer 218 also serves as the conductive seed layer for subsequent gold electrode plating. In one embodiment, the thickness of the gold encapsulation layer 218 is between 100 and 2,000 Angstroms. The gold encapsulating layer 218 may be formed by numerous deposition methods, such as sputtering, evaporation and plating. Alternative encapsulation materials include copper, silver, platinum, and their alloys as determined by the electrode metal used.

An electrode fabrication step 220 is then performed. Gold electrode contact areas 222 are defined by photolithography or by other techniques that are well known in the art. The gold electrode contact areas 222 are larger than the adhesion layer contact areas 214. Gold electrodes 224 are then formed by any method. In one embodiment, the gold electrodes 224 are formed by electroless plating or by electroplating. In other embodiments, the gold electrodes 224 are formed by sputtering or evaporation.

A second etching step 226 is performed to etch portions of the gold encapsulation layer 218 and the adhesion layer 206 outside of the gold electrode contact areas 222, thereby leaving the adhesion layer 206, the gold anti-oxidation layer 210, the gold encapsulation layer 218 and the gold electrode 224 in the gold electrode contact areas 222 only. Prior to the second etch, this layer 206, 218 serves as the conducting metal for electroplating, if electroplating is used to build up the electrode. If the electrode is not formed by electroplating, only the first etch is required. The second etch step 226 can be performed by numerous methods that are well known in the art. For example, the gold encapsulation layer 218 outside of the gold electrode contact area 222 can be defined lithographically and then chemically etched or etched using plasma etching or ion milling.

The resulting electrode structure 228 includes the gold electrodes 224 having an encapsulated adhesion layer. The gold electrodes 224 having the encapsulated adhesion layer are highly resistant to galvanic corrosion because the active metal in the adhesion layer 206 is encapsulated. Therefore, the active metal is not exposed to moisture.

While the invention has been particularly shown and described with reference to specific embodiments, it should be understood by those skilled in the art that various changes in form and detail may be made therein without departing from the spirit and scope of the invention as defined herein.

What is claimed is:

1. A multilayer metalized structure comprising:
a first adhesion layer of a first metal deposited on a substrate;
a second encapsulation layer of a second metal deposited upon the first layer, such that the second layer covers all edges of the first layer not in contact with the substrate.

2. A multiplayer metalized structure as defined in claim 1, wherein the substrate is selected from lithium niobate, lithium tantalite, silicon and gallium arsenide.

3. A multiplayer metalized structure as defined in claim 2, wherein the first adhesion layer is selected from chromium, titanium, titanium-tungsten, aluminum, nickel-chromium, tantalum, vanadium, and molybdenum.

4. A multiplayer metalized structure as defined in claim 3, wherein the encapsulation layer is selected from gold, copper, silver, platinum, and their alloys.

5. A multilayer electrode structure on a semiconductor device comprising:
a first adhesion layer of a first metal deposited on a substrate;
a second encapsulation layer of a second metal deposited upon the first layer, such that the second layer covers all edges of the first layer not in contact with the substrate;
an electrode layer of the second metal covering the encapsulation layer.

6. A multilayer electrode structure as defined in claim 5, wherein the substrate is selected from lithium niobate, lithium tantalite, silicon and gallium arsenide.

7. A multilayer electrode structure as defined in claim 6, wherein the first metal is selected from chromium, titanium, titanium-tungsten, aluminum, nickel-chromium, tantalum, vanadium, and molybdenum.

8. A multilayer electrode structure as defined in claim 7, wherein the second metal is selected from gold, copper, silver, platinum, and their alloys.

9. A method of forming a metalized structure on a substrate comprising the steps of:
depositing an adhesion layer of a first metal on a surface of the substrate;
etching the adhesion layer selectively to define contact areas;
depositing an encapsulation layer of a second metal on the surface of the substrate and upon the adhesion layer, such that the encapsulation layer covers all edges of the adhesion layer not in contact with the substrate;
fabricating a metalized structure over the encapsulation layer in the contact areas, the metalized structure being formed of a metal identical to or or having similar electrochemical potential to the encapsulation layer;
etching the encapsulation layer about the metalized structures in the contact areas.

10. The method as defined in claim 9, further including the deposition of an anti-oxidation layer over the adhesion layer, prior to the etching step to define contact areas.

11. The method as defined in claim 10, wherein the anti-oxidation layer comprises the second metal identical to the encapsulation layer.
